(19) United States
(12) Patent Application Publication
(10) Pub. No.: US 2022/0101141 A1
(43) Pub. Date: Mar. 31, 2022

(54) NEURAL NETWORK DEVICES BASED ON PHASE CHANGE MATERIAL

(71) Applicant: Samsung Electronics Co., Ltd., Suwon-si (KR)

(72) Inventors: Yunheub SONG, Seongnam-si (KR); Junseop AN, Seoul (KR); Cheng LI, Seoul (KR)

(73) Assignee: Samsung Electronics Co., Ltd., Suwon-si (KR)

(21) Appl. No.: 17/032,613

(22) Filed: Sep. 25, 2020

(51) Int. Cl. G06N 3/08; G06N 3/04

(52) U.S. Cl. CPC G06N 3/084; G06N 3/049

(57) ABSTRACT

A neural network device based on a phase-change material (PCM) includes a plurality of neurons that includes a first plurality of neurons in an input layer, a second plurality of neurons in a hidden layer, and a third plurality of neurons in an output layer. The neural network device includes a plurality of PCMs connecting an input line of the input layer to a connection line of the hidden layer and connecting the connection line of the hidden layer to an output line of the output layer. The first, second, and third pluralities of neurons have different structural configurations in different layers among the input layer, the hidden layer, and the output layer.

### BACKGROUND

The inventive concepts relate to neural network devices modeling the human nervous system based on a phase-change material (PCM).

According to the related art, a neural network device is modeled as a circuit, which includes a plurality of input drive amplifiers amplifying column input signals and a plurality of output drive amplifiers amplifying row output signals. In some example embodiments, the input drive amplifiers and the output drive amplifiers of the neural network device have the same structure (e.g., a structure including a reverse pulse driver, a forward pulse driver, and a winner-takes-all (WTA) driver) and each include a spike generator (SG) that generates a spike. A technique about such neural network device is disclosed in Korean Patent Publication 10-0183406.

This neural network device according to the related art needs to be updated through many operations to make a synaptic weight have an expected value.

### SUMMARY

The inventive concepts provide neural network devices capable of updating a synaptic weight in a single operation, the neural network devices modeling the human nervous system based on a phase-change material (PCM).

In some example embodiments, the inventive concepts provide PCM-based neural network devices capable of updating a synaptic weight in a single operation using a signal provided from a plurality of neurons having different module configurations in different layers.

According to some example embodiments of the inventive concepts, a neural network device based on a phase-change material (PCM) may include a plurality of neurons, the plurality of neurons including a first plurality of neurons in an input layer, a second plurality of neurons in a hidden layer, and a third plurality of neurons in an output layer. The neural network device may include a plurality of PCMs connecting an input line of the input layer to a connection line of the hidden layer and connecting the connection line of the hidden layer to an output line of the output layer. The first, second, and third pluralities of neurons may have different structural configurations in different layers among the input layer, the hidden layer, and the output layer.

According to some example embodiments of the inventive concepts, an operating method of a neural network device based on a phase-change material (PCM), where the neural network device includes a plurality of neurons that further includes a first plurality of neurons in an input layer, a second plurality of neurons in a hidden layer, and a third plurality of neurons in an output layer, may include controlling the first plurality of neurons of the input layer to configure the first plurality of neurons of the input layer to operate in a forward propagation write phase and to store data. The operating method may include controlling the second plurality of neurons of the hidden layer to configure the second plurality of neurons of the hidden layer to operate in the forward propagation write phase and to convert data provided from the first plurality of neurons of the input layer. The operating method may include controlling the third plurality of neurons of the output layer to configure the third plurality of neurons of the output layer to operate in the forward propagation write phase and to convert data provided from the second plurality of neurons of the hidden layer. The operating method may include controlling the third plurality of neurons of the output layer to configure the third plurality of neurons of the output layer to operate in a forward propagation read phase and to temporarily store an output signal of the output layer. The operating method may include selecting an operation on the output layer and storing a first decision result. The operating method may include selecting an operation on the hidden layer and storing a second decision result. The operating method may include updating a weight between the hidden layer and the output layer based on controlling the third plurality of neurons of the output layer to configure the third plurality of neurons of the output layer to operate in a backward propagation read phase and controlling the second plurality of neurons of the hidden layer to configure the second plurality of neurons of the hidden layer to operate in the forward propagation read phase. The operating method may include updating a weight between the input layer and the hidden layer based on controlling the second plurality of neurons of the hidden layer to configure the second plurality of neurons of the hidden layer to operate in the backward propagation read phase and controlling the first plurality of neurons of the input layer to configure the first plurality of neurons of the input layer to operate in the forward propagation read phase. The operating method may include refreshing the plurality of neurons.

### BRIEF DESCRIPTION OF THE DRAWINGS

Example embodiments of the inventive concepts will be more clearly understood from the following detailed description taken in conjunction with the accompanying drawings in which:

FIG. 1 is a diagram of a neural network device according to some example embodiments;

FIG. 2 is a diagram for describing neurons of an input layer of a neural network device, according to some example embodiments;

FIG. 3 is a diagram for describing neurons of a hidden layer of a neural network device, according to some example embodiments;

FIG. 4 is a diagram for describing neurons of an output layer of a neural network device, according to some example embodiments;

FIG. 5 is a diagram for describing a basic module in FIGS. 2 through 4, according to some example embodiments;

FIGS. 6, 7, 8, 9, and 10 are diagrams for describing phases of neurons, according to some example embodiments;

FIGS. 11, 12, and 13 are diagrams for describing a coding rule, a learning rule, and a decision rule of a neural network device, according to some example embodiments;

FIG. 14 is a flowchart of an operating method of a neural network device, according to some example embodiments; and

FIGS. 15, 16A, 16B, 17A, 17B, 18, 19, 20A, 20B, 21A, 21B, 22A, 22B, 23A, 23B, and 23C are diagrams for describing an operating method of a neural network device, according to some example embodiments.

### DETAILED DESCRIPTION

Hereinafter, some example embodiments will be described in detail with reference to the accompanying drawings. However, the inventive concepts are not limited thereto. In the drawings, like reference numerals denote like elements.

The terminology used herein is for the purpose of describing some example embodiments only and may vary with users' or operators' intentions or convention in the field of the art. Therefore, the terms used herein should be defined based on the overall content of the specification.

It will be understood, for example, that PCMs, which may be formed by using sputtering, chemical vapor deposition (CVD), plasma enhanced CVD (PECVD), atomic layer deposition (ALD), or the like, may include materials that may store data according to different crystalline states, including chalcogenide, a binary, tertiary, or quaternary material, Ge—Te, Ge—Sb—Te, Ge—Te—Se, Ge—Te—As, Ge—Te—Sn, Ge—Te—Ti, Ge—Bi—Te, Ge—Sn—Sb—Te, Ge—Sb—Se—Te, Ge—Sb—Te—S, Ge—Te—Sn—O, Ge—Te—Sn—Au, Ge—Te—Sn—Pd, Sb—Te, Se—Te—Sn, Sb—Se—Bi, In—Se, In—Sb—Te, Sb—Se, Ag—In—Sb—Te, or a combination thereof. In some example embodiments, a PCM may include a phase change material to which dopant is added, including C, N, Si, O, bismuth (Bi), tin (Sn), or a combination thereof. In some example embodiments, if a PCM is heated at temperature between a crystallization temperature and a melting temperature and then cooled, the PCM is changed into a crystalline state, a set state or a state in which data “0” is stored, and if the PCM is heated at a temperature higher than or equal to the melting temperature and then cooled, the PCM is changed into an amorphous state, a reset state or a state in which data “1” is stored.

For example, the material of the PCM layer may include Ge2Sb2Te5 with a thickness of 200 nm. The PCM may be coupled to a heater and electrodes. The material of the heater and electrodes may include tungsten, and the heater diameter may be 134 nm.

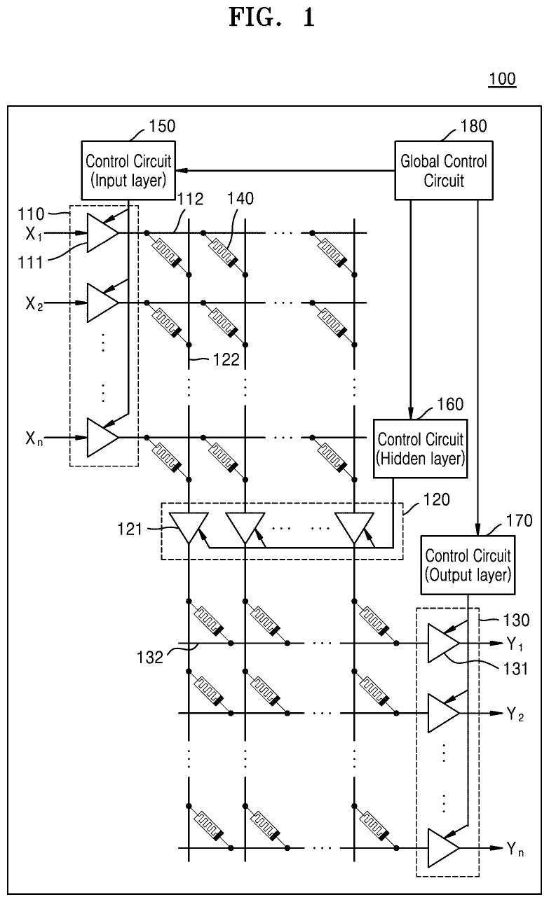

FIG. 1 is a diagram of a neural network device according to some example embodiments;

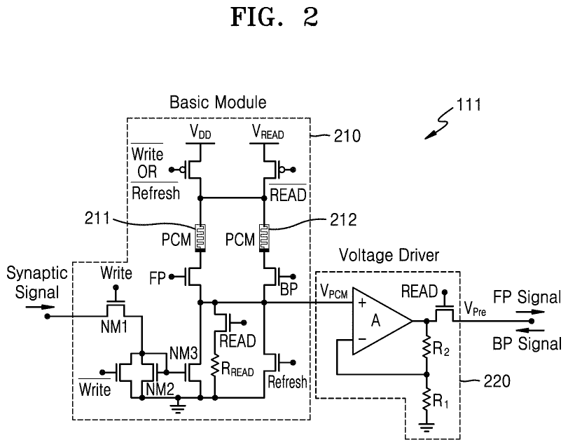

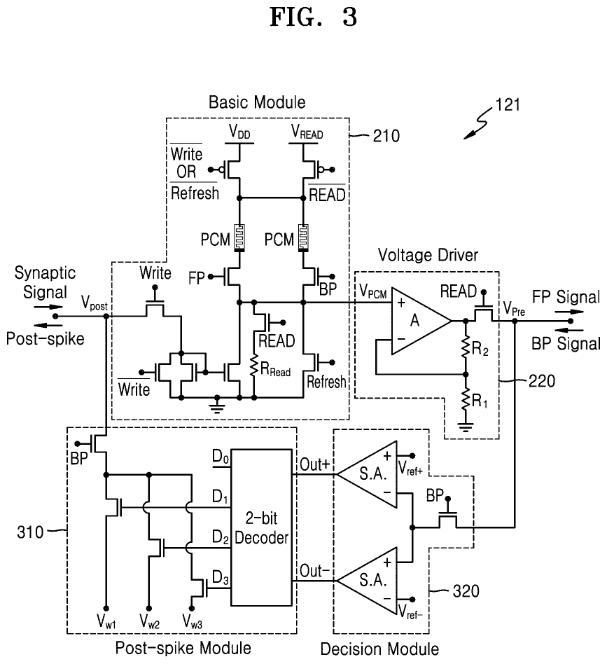

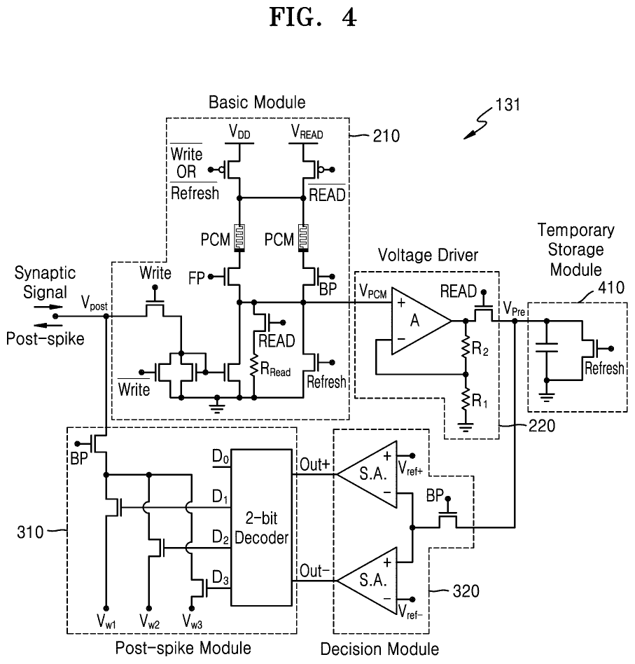

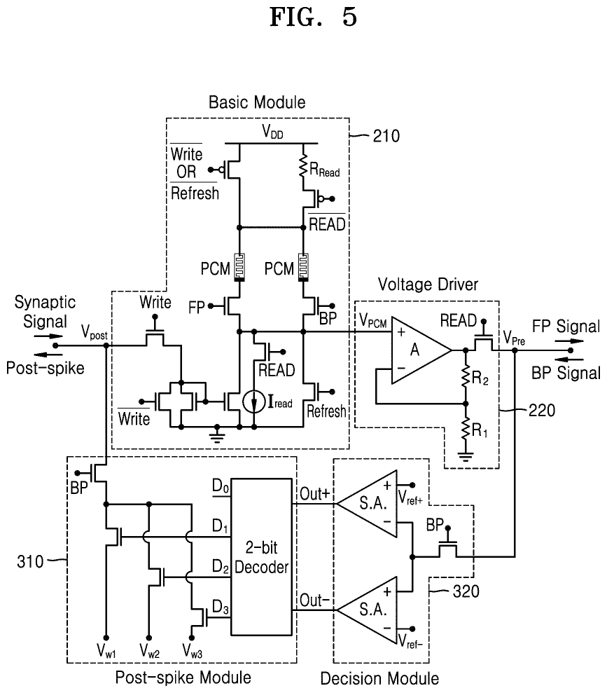

FIG. 2 is a diagram for describing neurons of an input layer of a neural network device, according to some example embodiments; FIG. 3 is a diagram for describing neurons of a hidden layer of a neural network device, according to some example embodiments; FIG. 4 is a diagram for describing neurons of an output layer of a neural network device, according to some example embodiments; and FIG. 5 is a diagram for describing a basic module in FIGS. 2 through 4, according to some example embodiments.

Referring to FIGS. 1 through 5, a neural network device 100 includes a plurality of neurons 111 in an input layer 110, a plurality of neurons 121 in a hidden layer 120, a plurality of neurons 131 in an output layer 130, and a plurality of phase-change materials (PCMs) 140 connecting an input line 112 (e.g., input wire, input conductive element, etc.) of the input layer 110 to a connection line 122 (e.g., connection wire, connection conductive element, etc.) of the hidden layer 120 and connecting the connection line 122 of the hidden layer 120 to an output line 132 (e.g., output wire, output conductive element, etc.) of the output layer 130. As described herein, the plurality of neurons 111 in the input layer 110, may be referred to as a “first” plurality of neurons in, or of, the input layer 110, the plurality of neurons 121 in the hidden layer 120 may be referred to as a “second” plurality of neurons in, or of, the hidden layer 120, the plurality of neurons 131 in the output layer 130 may be referred to as a “third” plurality of neurons in, or of, the output layer 130, and the pluralities of neurons 111, 121, 131 may be collectively referred to as a plurality of neurons of the neural network device 100.

The neurons 111, 121, and 131 have different module configurations (e.g., different structural configurations, including comprising different sets of modules and/or combinations thereof) in different layers. For example, neurons 111 may each include a same combination of modules (e.g., modules 210 and 220) that is different than the combinations of modules included in each of the neurons 121 and 131, neurons 121 may each include a same combination of modules (e.g., modules 210, 220, 310, and 320) that is different than the combinations of modules included in each of the neurons 111 and 131, and neurons 131 may each include a same combination of modules (e.g., modules 210, 220, 310, 320, 410) that is different than the combinations of modules included in each of the neurons 111 and 121. In some example embodiments, each of the neurons 111, 121, and 131 may include only modules configured to implement a particular (e.g., necessary) function in a corresponding layer (e.g., the layer in which the given neuron is included, where said particular function is a function that is associated with the corresponding layer) and may exclude (e.g., not include) a module (or any modules) configured to implement an unnecessary function in the corresponding layer (e.g., a function not associated with the corresponding layer). In other words, each of the neurons 111, 121, and 131 may have a different module configuration according to a layer in which each of the neurons 111, 121, and 131 is located (e.g., is included).

For example, the neurons 111 of the input layer 110 may include only modules for implementing (e.g., modules configured to implement) a function associated with processing (e.g., necessary to process) an input pulse (a signal or data), the neurons 121 of the hidden layer 120 may include only modules for implementing a function of transmitting pulses from the neurons 111 of the input layer 110 to the neurons 131 of the output layer 130, and the neurons 131 of the output layer 130 may include only modules for implementing a function associated with processing (e.g., necessary to process) output pulses.

In detail, each of the neurons 111 of the input layer 110 may include a basic module 210 and a voltage driver 220, as shown in FIG. 2; each of the neurons 121 of the hidden layer 120 may include the basic module 210, the voltage driver 220, a post-spike module 310, and a decision module 320, as shown in FIG. 3; and each of the neurons 131 of the output layer 130 may include the basic module 210, the voltage driver 220, the post-spike module 310, the decision module 320, and a temporary storage module 410, as shown in FIG. 4. The function and operation of each module will be described below. It will be understood, as shown in FIGS. 2-4, that similar modules in separate neurons 111, 121, 131 may have a common structure. For example, as shown in FIGS. 2-4, the basic modules 210 in the separate neurons 111, 121, 131 may be separate basic modules 210 that have a common (e.g., same) structure, the voltage drivers 220 in the separate neurons 111, 121, 131 may be separate voltage drivers 220 that have a common (e.g., same) structure, the decision modules 320 in the separate neurons 121, 131 may be separate the decision modules 320 that have a common (e.g., same) structure, the post-spike modules 310 in the separate neurons 121, 131 may be separate post-spike modules 310 that have a common (e.g., same) structure, and the temporary storage modules 410 in the separate neurons 131 may be separate temporary storage modules 410 that have a common (e.g., same) structure. As shown in FIGS. 2-4, each of the modules 210, 310, 410 and voltage driver 220 may include separate instances, articles, etc. of circuitry, and thus the basic module 210 may be referred to herein as a “basic circuitry,” the voltage driver 220 may be referred to herein as a “voltage driver circuitry,” the post-spike module 310 may be referred to herein as “post-spike circuitry,” the decision module 320 may be referred to herein as “decision circuitry,” and the temporary storage module 410 may be referred to herein as “temporary storage circuitry.”

It will be understood that each of the neurons 111, 121, 131 may, in some example embodiments, include any combination of any of the modules 210, 310, 320, and/or 410 and/or the voltage driver 220 as described herein with regard to any of the drawings. For example, in some example embodiments, each of the neurons 111, 121, 131 may include a basic module 210, voltage driver 220, post-spike module 310, decision module 320, and temporary storage module 410.

The basic module 210 may include a first PCM device 211 storing (e.g., configured to store) a forward propagation signal and a second PCM device 212 storing (e.g., configured to store) a backward propagation signal.

The basic module 210 may include a resistor, a plurality of PCM devices, and a plurality of MOSFETs. These MOSFETs may act as switches controlled by digital signals. A first MOSFET NM1 may perform as a current generator generating the corresponding current from the voltage perceived by the terminal Vpost. A second MOSFET NM2 and a third MOSFET NM3 may construct a current mirror that converts the current generated by the first MOSFET NM1 into a write current to program the PCM devices 211, 212. In addition to the basic voltage supply VDD and VSS, a small enough voltage VRead may be required to read the PCM devices 211, 212 storage data. When the neural network device 100 starts working, the resistance of both PCM devices 211, 212 may be initialized to the maximum by a Refresh operation. In subsequent Write operations, the signal from the Vpost terminal is written into the specific PCM device, either the first PCM device 211 or the second PCM device 212. During the read operation, the data stored in the specific PCM device is read out and a corresponding voltage signal is passed to the voltage driver 220.

The voltage driver 220 may provide (e.g., may be configured to provide, generate, transmit, output, etc.) an output signal in a read range.

The voltage driver 220 may contain an OP AMP, a plurality of resistors R1, R2, and a MOSFET performed as a switch. A voltage signal from the basic module 210 is received and proportionally converted into a voltage signal within a specified range to drive the synapse array or pass to the decision module 320.

The post-spike module 310 may provide (e.g., may be configured to provide, generate, transmit, output, etc.) a post-spike to update a synaptic weight during a backward propagation read phase, provide a backward propagation signal during the backward propagation read phase, and provide a write signal for writing at a PCM neuron during a backward propagation write phase.

The post-spike module 310 may include a 2-bit decoder and a plurality of MOSFETs as switches. The post-spike module 310 may receive the decision signal from the decision module 320 and control the switch to pass the corresponding voltage value to the Vpost terminal.

The decision module 320 may compare (e.g., may be configured to compare) a backward propagation signal with a reference (e.g., reference signal) and determine suitability for a test or select an operation (e.g., long-term potentiation (LTP), long-term depression (LTD), or no change) for learning.

The decision module 320 may include a plurality of Sense Amplifiers, there are three inputs and two outputs. The reference voltages V_{ref+} and V_{ref-} each are the sum and difference of the original reference voltage and ½ margin, respectively. The decision module 320 may receive a BP signal from outside the circuit or a voltage signal from the voltage driver 220. Then the decision module 320 may compare it with the positive and negative reference voltage, respectively.

As shown in Table 1 below, three possible results can be obtained: the signal Vₚᵣₑ is much higher than the reference voltage V_{ref+}, or the signal Vₚᵣₑ is much lower than the reference voltage V_{ref-}, or the signal Vₚᵣₑ is near both the reference voltage V_{ref-} and the reference voltage V_{ref+}. The decision module 320 may decide based on the comparison results and pass the decision signal to the post-spike module 310.

TABLE 1

| | Out+ | Out− |
|---|---|---|
| Vₚᵣₑ < V_{ref-} | 1 | 0 |
| V_{ref-} ≤ Vₚᵣₑ ≤ V_{ref+} | 1 | 1 |
| Vₚᵣₑ > V_{ref+} | 0 | 1 |

The temporary storage module 410 may store (e.g., may be configured to store) an output signal of the output layer 130 during a forward propagation read phase.

The temporary storage module 410 may include a capacitor and a MOSFET as a switch. The temporary storage module 410 may be used for neurons in the output layer 130, and the terminal may be connected to the output of the voltage driver 220. At the end of the forward propagation, the neurons in the output layer 130 may store the actual output signal temporarily in the capacitor in the form of voltage to facilitate subsequent comparison with the expected output. In the Refresh phase, the switch may be turned on to connect the capacitor to GND, clearing the stored voltage signal.

In some example embodiments, the circuit configuration of the basic module 210 is not limited to structures in FIGS. 2 through 4 and may have a structure in FIG. 5. Due to this structural difference, a PCM voltage V_{PCM} in the basic module 210 in FIGS. 2 through 4 may be calculated by Formula 1, and the PCM voltage V_{PCM} in a basic module 210 may be calculated by Formula 2.

V_{PCM}=V_{READ}*R_{read}(R_{PCM}+R_{Read}) <Formula 1>

V_{PCM}=V_{DD}−I_{read}*(R_{PCM}+R_{Read}) <Formula 2>

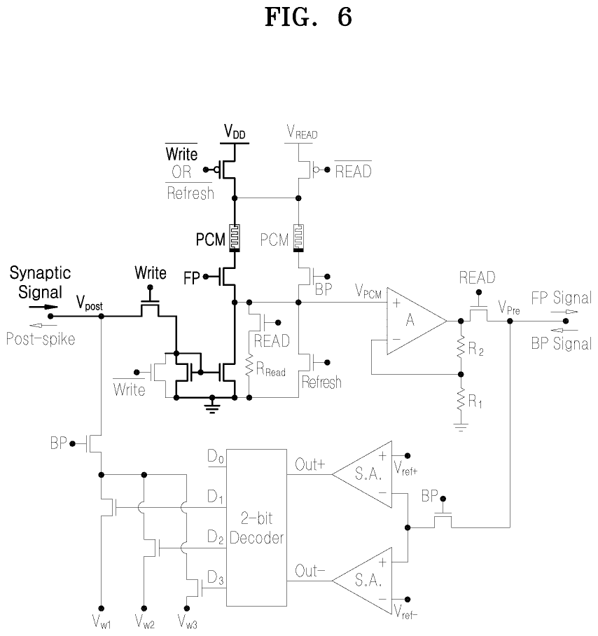

The neural network device 100, which includes the neurons 111, 121, and 131 having different module configurations (e.g., different structural configurations) in different layers, may update (e.g., may be configured to update) a weight between the hidden layer 120 and the output layer 130 and may further update a weight between the input layer 110 and the hidden layer 120 in a single operation (e.g., update both weights in a single operation) according to a post-spike provided from each of the neurons 131 of the output layer 130 (e.g., provided from each neuron 131 of the neurons 131 of the output layer 130) and the neurons 121 of the hidden layer 120, based on the above-described structure. Phases of the neurons 111, 121, and 131 related to this characteristic will be described in detail with reference to FIGS. 6 through 10 below.

Each of the PCMs 140 is crystallized in response to a crystallizing current and realizes multiple bits. Each of the PCMs 140 is the same as a capacitive PCM used in a neural network device according to the related art, and thus detailed descriptions thereof will be omitted.

The neural network device 100 may further include at least one control circuit to (e.g., configured to) synchronize the timings of pulses output from the neurons 111, 121, and/or 131 (e.g., to synchronize the timings of pulses output from one or more neurons of the plurality of neurons of the neural network device 100, including one or more of any of the neurons 111, 121, and/or 131). Here, the at least one control circuit may be provided for each layer. In some example embodiments, the neural network device 100 may include at least one control circuit that is configured to synchronize timings of pulses that are output from (e.g., transmitted, generated, etc.) each and/or all of the neurons 111 of the input layer 110, the neurons 121 of the hidden layer 120, and the neurons 131 of the output layer 130. In some example embodiments, the neural network device 100 may include a plurality of control circuits that are configured to synchronize timings of pulses that are output from separate, respective pluralities of neurons of the neurons 111 of the input layer 110, the neurons 121 of the hidden layer 120, and the neurons 131 of the output layer 130. Restated, the neural network device 100 may include a plurality of control circuits that are each configured to synchronize timings of pulses that are output from a separate plurality of neurons of the neurons 111 of the input layer 110, the neurons 121 of the hidden layer 120, or the neurons 131 of the output layer 130.

For example, as shown in at least FIG. 1, a neural network device 100 may include a level 1 control circuit 150 that is provided to (e.g., is configured to) synchronize the timings of pulses output from (e.g., transmitted by, generated by, etc.) the neurons 111 of the input layer 110, a level 2 control circuit 160 that is provided to (e.g., is configured to) synchronize the timings of pulses output from (e.g., transmitted by, generated by, etc.) the neurons 121 of the hidden layer 120, and a level 3 control circuit 170 that is provided to (e.g., is configured to) synchronize the timings of pulses output from (e.g., transmitted by, generated by, etc.) the neurons 131 of the output layer 130. As shown in at least FIG. 1, a neural network device 100 may further include a global control circuit 180 that may be further provided to (e.g., may be further configured to) control the level 1 control circuit 150, the level 2 control circuit 160, and the level 3 control circuit 170. Accordingly, the neural network device 100 includes at least one control circuit, which may include the global control circuit 180 and a plurality of sub control circuits that are controlled based on the global control circuit 180 and are configured to synchronize timings of pulses that are output from separate, respective pluralities of neurons of the neurons 111, 121, and 131. For example, the plurality of sub control circuits may include the level 1 control circuit 150, the level 2 control circuit 160, and the level 3 control circuit 170. The global control circuit 180 may be configured to control the level 1 control circuit 150, the level 2 control circuit 160, and the level 3 control circuit 170, such that the neurons 111, 121, and 131 output (e.g., generate, transmit, etc.) pulses at the same timing and operate in synchronization with one another.

The neural network device 100 and/or any portions thereof, including one or more of the control circuits of the neural network device 100 (e.g., one or more of the level 1 control circuit 150, the level 2 control circuit 160, the level 3 control circuit 170, and/or the global control circuit 180), and/or any portions thereof, may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device, for example a solid state drive (SSD), storing a program of instructions, and a processor configured to execute the program of instructions to implement the functionality and/or methods performed by some or all of the neural network device 100, including the functionality and/or methods performed by some or all of the level 1 control circuit 150, the level 2 control circuit 160, the level 3 control circuit 170, and/or the global control circuit 180.

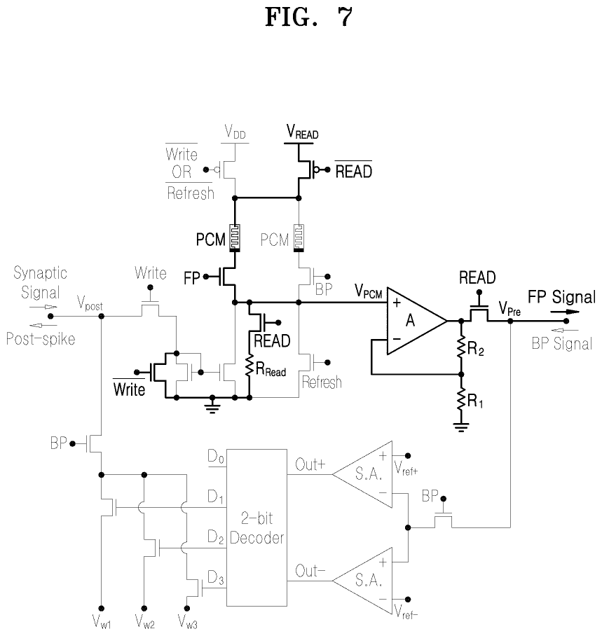

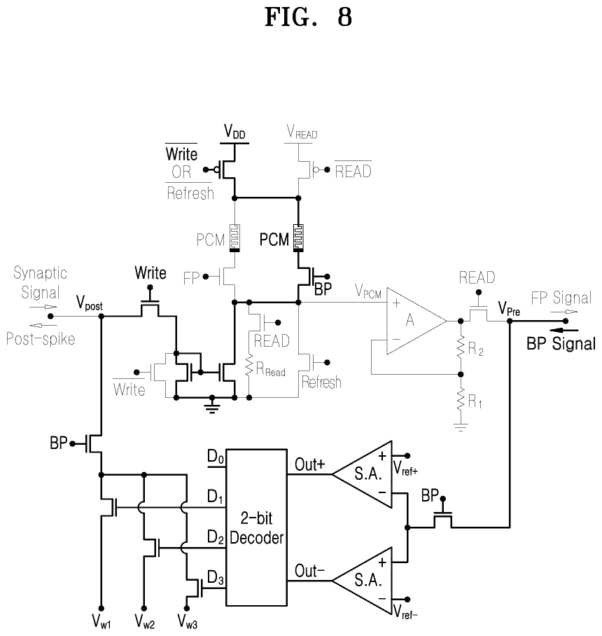

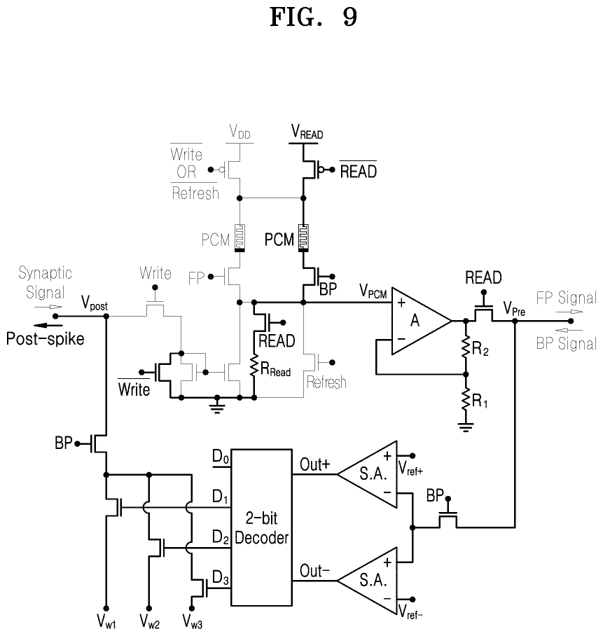

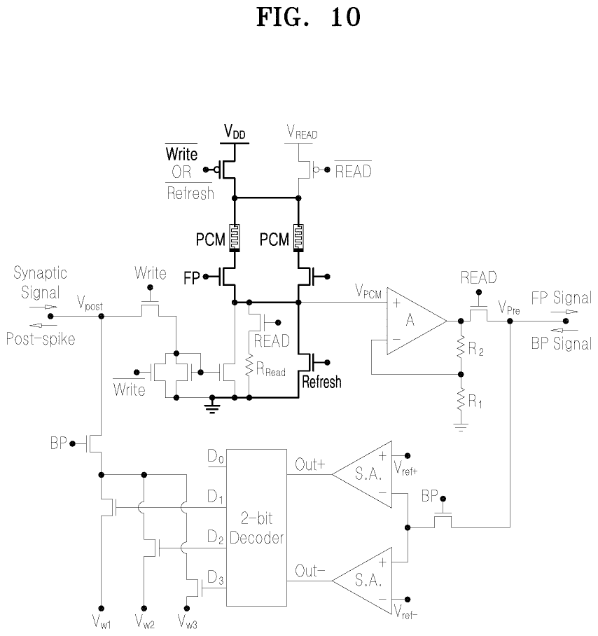

FIGS. 6 through 10 are diagrams for describing phases of neurons, according to some example embodiments. In detail, FIG. 6 is a diagram showing elements activated in a forward propagation write phase among the elements of a neuron; FIG. 7 is a diagram showing elements activated in a forward propagation read phase among the elements of a neuron; FIG. 8 is a diagram showing elements activated in a backward propagation write phase among the elements of a neuron; FIG. 9 is a diagram showing elements activated in a backward propagation read phase among the elements of a neuron; and FIG. 10 is a diagram showing elements activated in a refresh phase among the elements of a neuron. Although activated elements of a neuron of a hidden layer will be described with reference to FIGS. 6 through 10 below, embodiments are not limited thereto. The same elements of a neuron of each of an input layer and an output layer may also be activated or deactivated.

Referring to FIGS. 6 through 10, according to some example embodiments, neurons of a neural network device may operate in five phases including a forward propagation write phase, a forward propagation read phase, a backward propagation write phase, a backward propagation read phase, and a refresh phase.

In the forward propagation write phase, only elements illustrated dark in FIG. 6 are activated and elements illustrated pale in FIG. 6 are deactivated so that forward propagation signals are combined into a synaptic signal and the synaptic signal is converted into a neuron. In the forward propagation write phase, data (or a synaptic signal) may be written to and stored in a first PCM device of each neuron.

In the forward propagation read phase, only elements illustrated dark in FIG. 7 are activated and elements illustrated pale in FIG. 7 are deactivated so that the data (or the synaptic signal) stored in the first PCM device may be read and a forward propagation signal Vₚᵣₑ may be provided based on the read data.

In the backward propagation write phase, only elements illustrated dark in FIG. 8 are activated and elements illustrated pale in FIG. 8 are deactivated so that backward propagation signals are incorporated the neuron. In the backward propagation write phase, the backward propagation signal may be compared with a reference, a decision result may be generated, and a write pulse may be generated based on the decision result and may be written to and stored in a second PCM device.

In the backward propagation read phase, only elements illustrated dark in FIG. 9 are activated and elements illustrated pale in FIG. 9 are deactivated so that the data (or the write pulse) stored in the second PCM device may be read, the forward propagation signal Vₚᵣₑ may be compared with a reference V₁/2 to generate a decision result, and a post-spike 0V, −V₁, or −V₃ or a backward propagation signal V_{high}, V_{mid}, or V_{low} based on the decision result.

In the refresh phase, only elements illustrated dark in FIG. 10 are activated and elements illustrated pale in FIG. 10 are deactivated so that the first PCM device and the second PCM devices may be reset to an initial state.

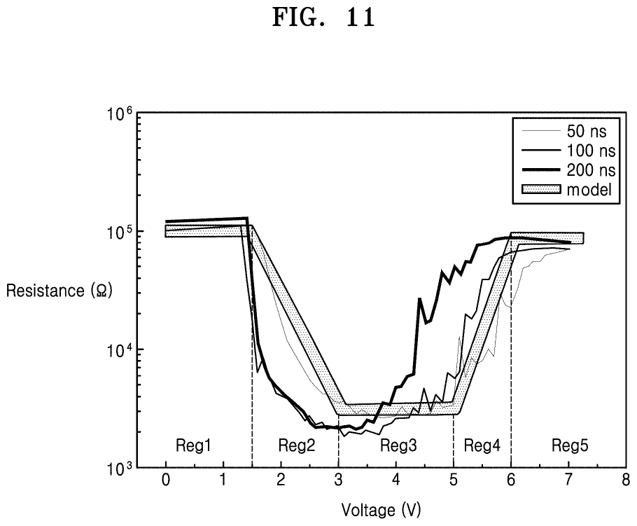

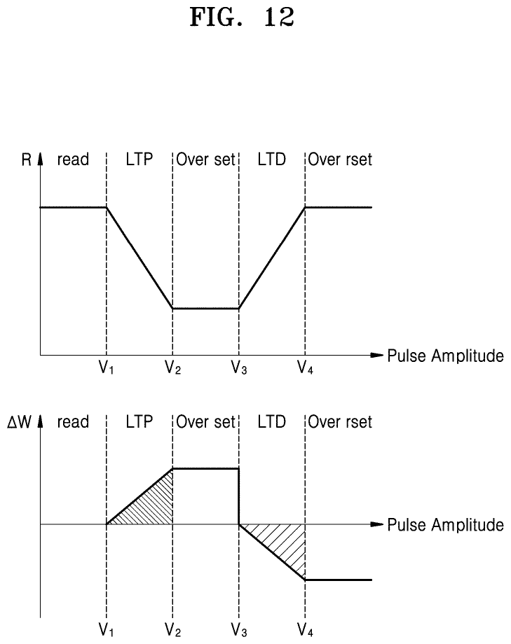

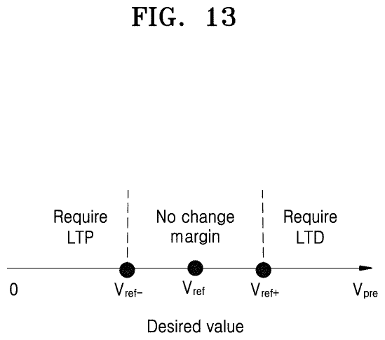

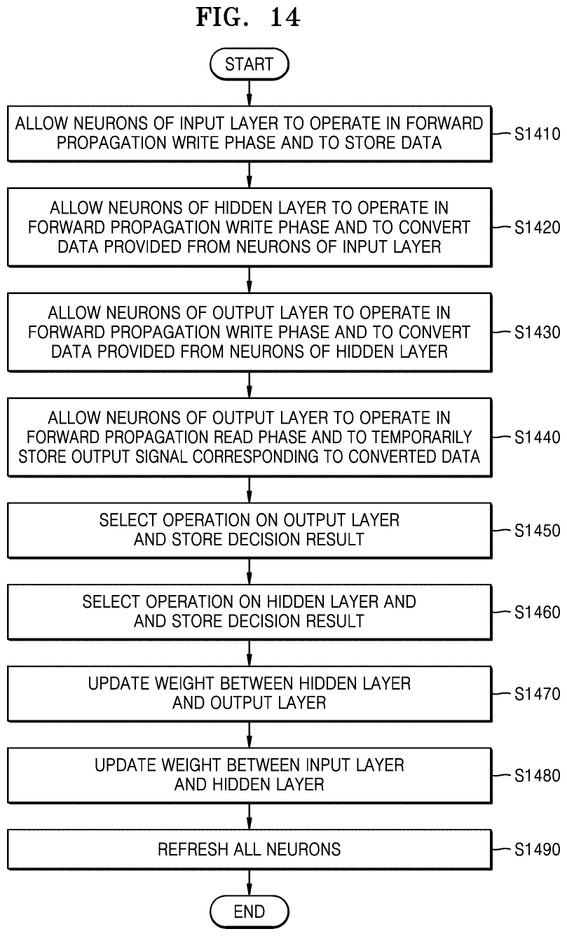

A coding rule, a learning rule, and a decision rule of a neural network device, which operates based on the phases described above, will be described in detail with reference to FIGS. 11 through 13, and an operating method of the neural network device will be described in detail with reference to FIGS. 14 through 22.

FIGS. 11 through 13 are diagrams for describing the coding rule, the learning rule, and the decision rule of the neural network device, according to some example embodiments.

Referring to FIG. 11, the chart shown in FIG. 11 shows experimental test data showing the response of the PCM resistance to the programming pulse with different amplitudes. The rising time and falling time are set as 30 nm. The pulse widths are set to 50 ns, 100 ns, and 200 ns, respectively. The read voltage is set as 0.1 V. Referring to the chart, neural network device 100 may be separated into five regions Reg1, Reg2, Reg3, Reg4, and Reg5 based on the amplitude of the programming pulse. In the read region Reg1, the PCM device maintains its resistance. In the set region Reg2, the resistance of the PCM device decreases, and the decrease may be proportional to the amplitude. In the over-set region Reg3, the resistance of the PCM device decreases to a minimum value. In the reset region Reg4, the resistance increases; this increment may be proportional to the amplitude. In the over-reset region Reg5, the PCM device is reset into a fully amorphous state.

Referring to FIGS. 11 through 13, according to some example embodiments, the neural network device may write a current signal to PCM devices so as to generate different resistance values in a write phase and may read a PCM resistance and output a pulse having a different amplitude based on the PCM resistance in a read phase. The pulse may correspond to the forward propagation signal Vₚᵣₑ. In some example embodiments, the amplitude of the pulse may be limited to a read range of 0V to V₁, as shown in Table 2 below.

TABLE I

| | | V_{PCM} | |
|---|---|---|---|
| Vₚᵣₑ | Vₚₒₛₜ | (Vₚᵣₑ − Vₚₒₛₜ) | Operation |
| 0 to V₁ | 0 | 0 to V₁V₂ | Read |
| 0 to V₁ | −V₁ | V₁ to V₂ | LTP |
| 0 to V₁ | V₃ to V₄ | V₃ to V₄ | LTD |

Regarding the learning rule, changes in PCM resistance are shown in Table 3. In detail, a PCM resistance R_{PCM} may not change in the read range of 0 to V₁ (wherein a weight remains constant), may decrease according to the amplitude in the LTP range of V₁ to V₂ (wherein the weight increases), may decrease to a minimum value in the range of V₂ to V₃ (wherein the weight is not used), may increase according to the amplitude in the LTD range of V₃ to V₄ (wherein the weight decreases), and may increase to a maximum value in an over-reset range (wherein the weight is not used).

TABLE 3

| OUT+ | OUT− | Learning operation | Test result |
|---|---|---|---|
| 0 | 0 | Not exist | Not exist |
| 0 | 1 | LTD | Wrong |
| 1 | 0 | LTP | Wrong |
| 1 | 1 | Not change | Right |

Regarding the decision rule, a desired output value may be designated as V_{ref}, and V_{margin} may be designated as shown in Formulas 3 through 6.

V_{ref+}=V_{ref}+(1/2)V_{margin}

V_{ref-}=−(1/2)V_{margin} <Formula 3>

Vₚᵣₑ<V_{ref}: LTP(weight increase)(wrong) <Formula 4>

V_{ref-}≤Vₚᵣₑ≤V_{ref+}: no operation(right) <Formula 5>

Vₚᵣₑ>V_{ref+}: LTP(weight decrease)(wrong) <Formula 6>

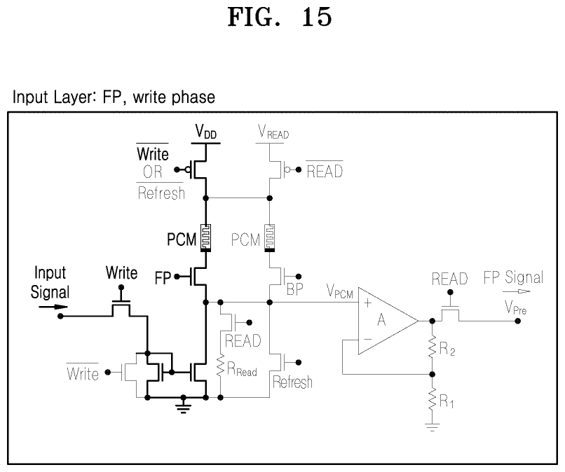

FIG. 14 is a flowchart of an operating method of a neural network device, according to some example embodiments; and FIGS. 15 through 23 are diagrams for describing an operating method of a neural network device, according to some example embodiments. It will be understood that the operating method shown in FIG. 14 and further illustrated in FIGS. 15-23 may be implemented by any of the neural network devices according to any of the example embodiments. In some example embodiments, some or all of the operations of the method shown in FIG. 14 are implemented by one or more of the control circuits of the neural network device 100 (e.g., one or more of control circuits 150, 160, 170, 180) based on said one or more control circuits controlling some or all (e.g., one or more modules/circuitries of) one or more, or all, of the neurons 111, 121, and/or 131.

Referring to FIGS. 14 through 23, neurons of an input layer (e.g., neurons 111) are allowed to (e.g., are caused to) operate in a forward propagation write phase and store data in operation S1410 in a state where only elements illustrated dark in FIG. 15 are activated and elements illustrated pale in FIG. 15 are deactivated. Operation S1410 may be implemented based on one or more control circuits of the neural network device 100 (e.g., control circuit 150 and/or 180) controlling some or all of the input layer 110, including controlling some or all of the neurons 111 of the input layer 110.

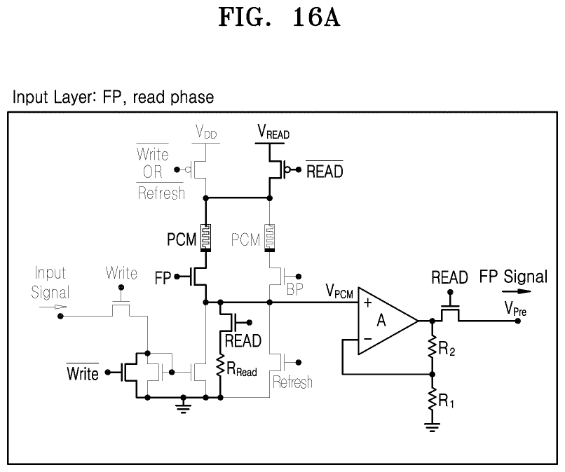

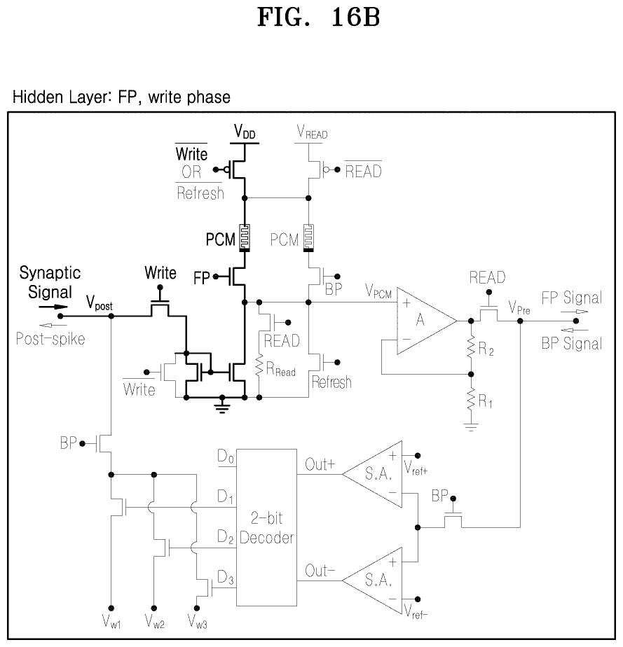

Neurons of a hidden layer are allowed to (e.g., are caused to and/or are controlled to be configured to) operate in the forward propagation write phase and convert the data provided from the neurons of the input layer in operation S1420. In detail, in operation S1420, in a state where only elements illustrated dark in FIGS. 16A and 16B are activated and elements illustrated pale in FIGS. 16A and 16B are deactivated, as the neurons of the input layer (e.g., neurons 111, as shown in FIG. 16A) operate (e.g., concurrently with the neurons of the input layer operating) in a forward propagation read phase, the neurons of the hidden layer (e.g., neurons 121, as shown in FIG. 16B) operate (e.g., are caused to operate and/or are controlled to be configured to operate) in the forward propagation write phase and may combine forward propagation signals Vₚᵣₑ provided (e.g., output) from the neurons of the input layer into a synaptic signal and store the synaptic signal. Operation S1420 may be implemented based on one or more control circuits of the neural network device 100 (e.g., control circuit 160 and/or 180) controlling some or all of the hidden layer 120, including controlling some or all of the neurons 121 of the hidden layer 120.

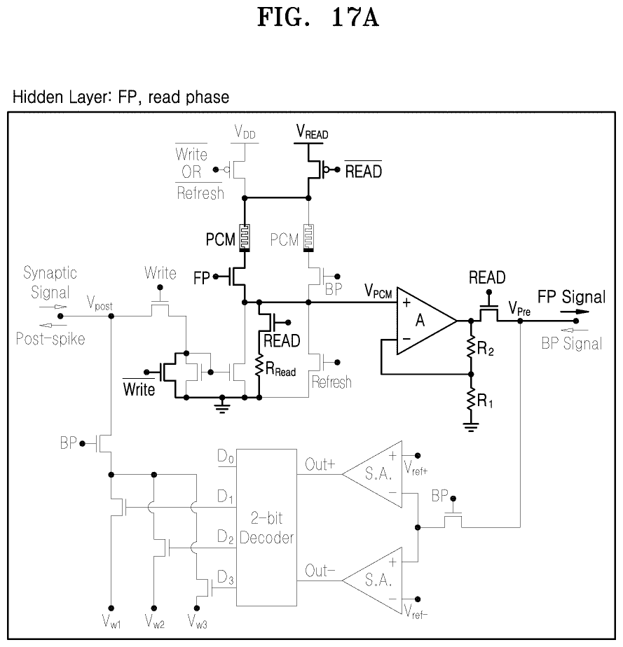

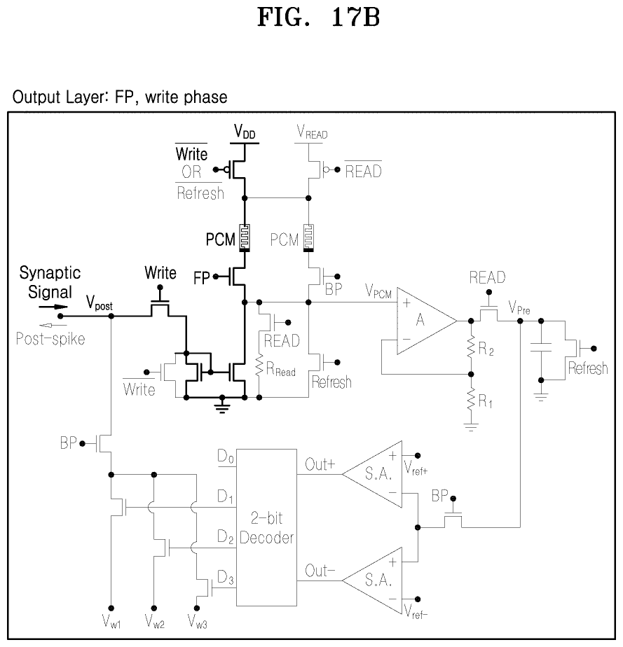

Neurons of an output layer are allowed to (e.g., are caused to and/or are controlled to be configured to) operate in the forward propagation write phase and convert the data provided from the neurons of the hidden layer in operation S1430. In detail, in operation S1430, in a state where only elements illustrated dark in FIGS. 17A and 17B are activated and elements illustrated pale in FIGS. 17A and 17B are deactivated, as the neurons of the hidden layer (e.g., neurons 121, as shown in FIG. 17A) operate (e.g., concurrently with the neurons of the hidden layer operating) in the forward propagation read phase, the neurons of the output layer (e.g., neurons 131, as shown in FIG. 17B) operate (e.g., are caused to operate and/or are controlled to be configured to operate) in the forward propagation write phase and may combine forward propagation signals Vₚᵣₑ provided from (e.g., output from) the neurons of the hidden layer into a synaptic signal and store the synaptic signal. Operation S1430 may be implemented based on one or more control circuits of the neural network device 100 (e.g., control circuit 170 and/or 180) controlling some or all of the output layer 130, including controlling some or all of the neurons 131 of the output layer 130.

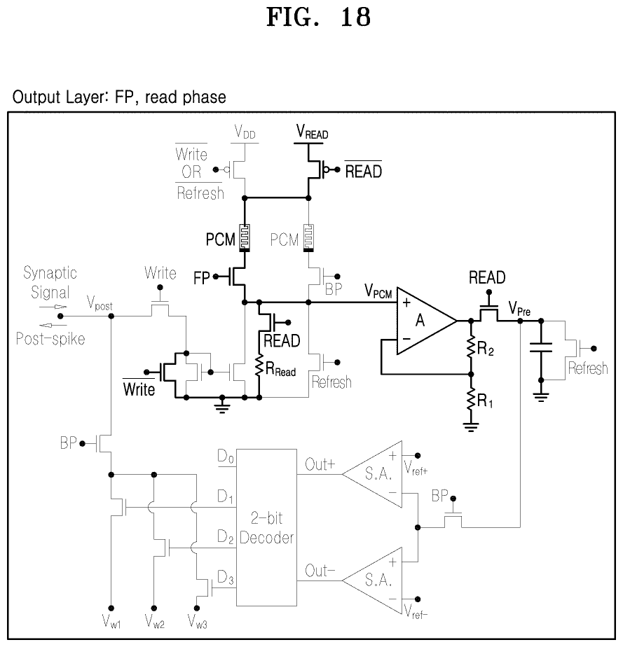

The neurons of the output layer are allowed to (e.g., are caused to and/or are controlled to be configured to) operate in the forward propagation read phase and temporarily store an output signal corresponding to the converted data (e.g., an output signal of the output layer) in operation S1440 in a state where only elements illustrated dark in FIG. 18 are activated and elements illustrated pale in FIG. 18 are deactivated.

The term “Temporarily” may mean that the data is only valid for one iteration. For example, a neuronal circuit may need to be refreshed at the beginning of the new iteration, and a temporary storage data can be deleted. For example, the workflow of an iteration may be performed as shown in Table 4, for a 3-layer neural network.

TABLE 4

| Step | Input Layer | Hidden Layer | Output Layer | |
|---|---|---|---|---|
| # | 110 | 120 | 130 | Description |
| 1 | FP write | | | Store data into input neuron 111 |
| 2 | FP read | FP write | | Data transform to hidden layer 120 |
| 3 | | FP read | FP write | Data transform to output layer 130 |
| 4 | | | FP read | Temporary storage of output voltage |
| 5 | | | BP write | Calculate and store the error in output |
| | | | | layer 130 |
| 6 | | BP write | BP read | Back propagating the error to hidden |
| | | | | layer 120 |
| 7 | | FP read | BP read | Weight updating between hidden layer |
| | | | | 120 and output layer 130 |
| 8 | FP read | BP read | | Weight updating between input layer |
| | | | | 110 and hidden layer 120 |
| 9 | Refresh | Refresh | Refresh | Refresh and prepare for next iteration |

The output signal may correspond to the forward propagation signal Vₚᵣₑ. Operation S1440 may be implemented based on one or more control circuits of the neural network device 100 (e.g., control circuit 170 and/or 180) controlling some or all of the output layer 130, including controlling some or all of the neurons 131 of the output layer 130.

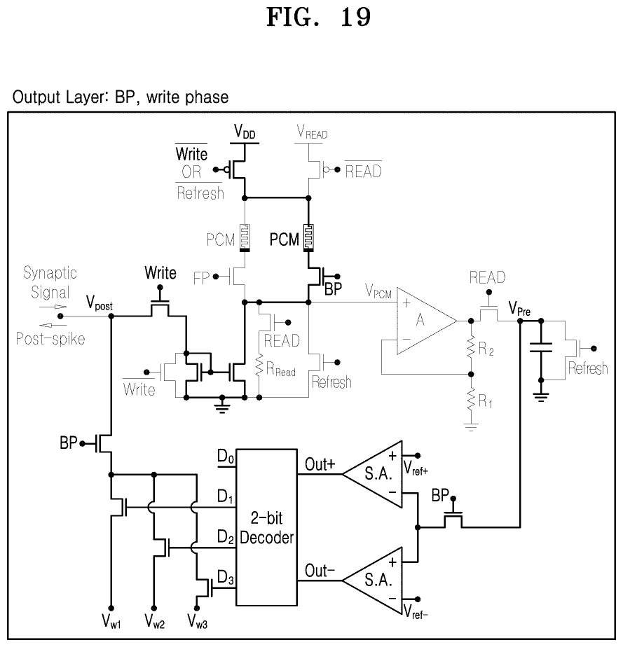

An operation on the output layer is selected and a decision result (e.g., a first decision result) is stored in operation S1450. In detail, in operation S1450, in a state where only elements illustrated dark in FIG. 19 are activated and elements illustrated pale in FIG. 19 are deactivated, the neurons of the output layer (e.g., neurons 131, as shown in FIG. 19) operate (e.g., are caused to operate and/or are controlled to be configured to operate) in a backward propagation write phase and may compare a combined backward propagation signal with a first reference V_{label} and store the decision result in the hidden layer (wherein V_{W,high}, V_{W,mid}, or V_{W,low} is provided). The neurons of the output layer may operate (e.g., may be caused to operate and/or are controlled to be configured to operate) in a backward propagation write phase to compare a combined backward propagation signal with a first reference V_{label} and to store the decision result in the hidden layer (wherein V_{W,high}, V_{W,mid}, or V_{W,low} is provided). Operation S1450 may be implemented based on one or more control circuits of the neural network device 100 (e.g., control circuits 160, 170 and/or 180) controlling some or all of the output layer 130, including controlling some or all of the neurons 131 of the output layer 130 and/or some or all of the neurons 121 of the hidden layer 120.

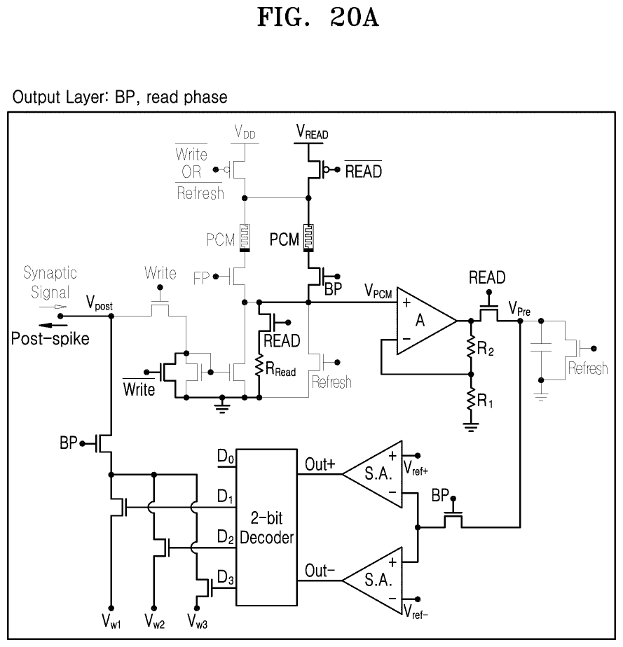

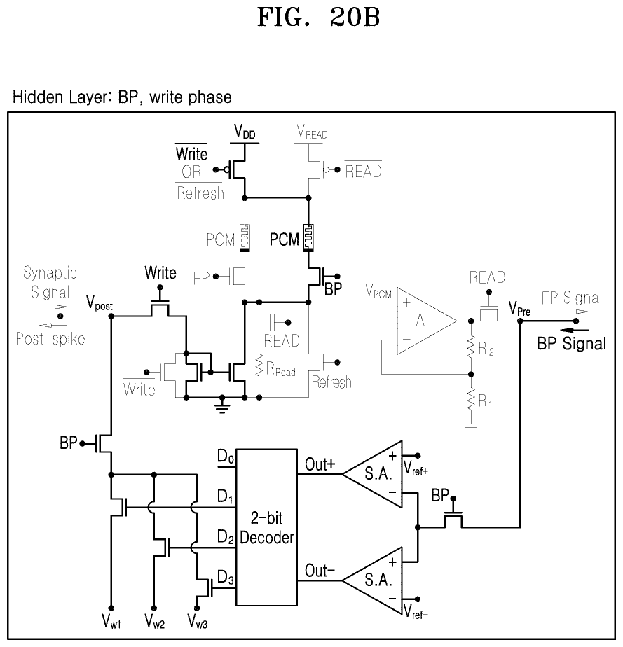

An operation on the hidden layer is selected and a decision result (e.g., a second decision result) is stored in operation S1460. In detail, in operation S1460, in a state where only elements illustrated dark in FIGS. 20A and 20B are activated and elements illustrated pale in FIGS. 20A and 20B are deactivated, as the neurons of the output layer (e.g., neurons 131, as shown in FIG. 20A) operate (e.g., are caused to operate and/or are controlled to be configured to operate) in a backward propagation read phase (e.g., concurrently with the neurons of the output layer operating, being caused to operate, and/or being controlled to be configured to operate), the neurons of the hidden layer (e.g., neurons 121, as shown in FIG. 20B) operate (e.g., are caused to operate and/or are controlled to be configured to operate) in the backward propagation write phase and may combine the backward propagation signals V_{W,high}, V_{W,mid}, and V_{W,low} provided from the neurons of the output layer, compare a combination result with a second reference V_{mid}, and store a decision result therein (wherein V_{W,high}, V_{W,mid}, or V_{W,low} is provided). The neurons of the hidden layer may operate (e.g., may be caused to operate and/or are controlled to be configured to operate) in the backward propagation write phase, to combine the backward propagation signals V_{W,high}, V_{W,mid}, and V_{W,low} provided from the neurons of the output layer, to compare a combination result with a second reference V_{mid}, and to store a decision result therein (wherein V_{W,high}, V_{W,mid}, or V_{W,low} is provided). Operation S1460 may be implemented based on one or more control circuits of the neural network device 100 (e.g., control circuit 160, 170, and/or 180) controlling some or all of output layer 130 and/or the hidden layer 120, including controlling some or all of the neurons 131 of the output layer 130 and/or the neurons 121 of the hidden layer 120.

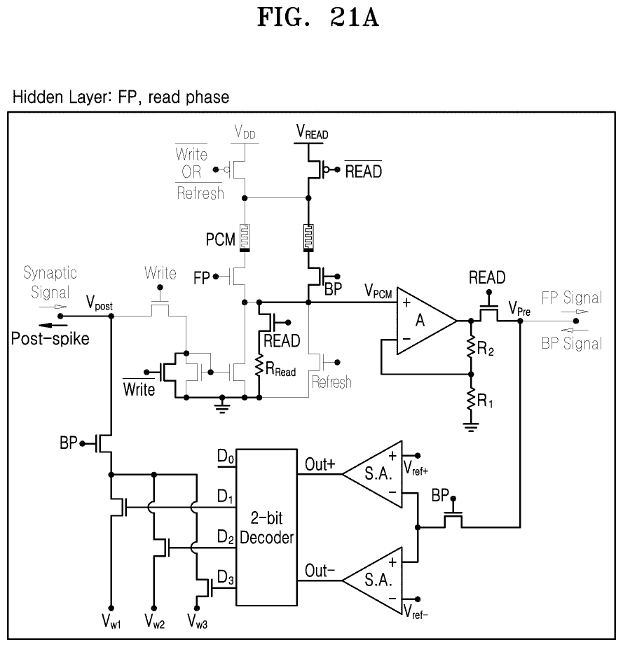

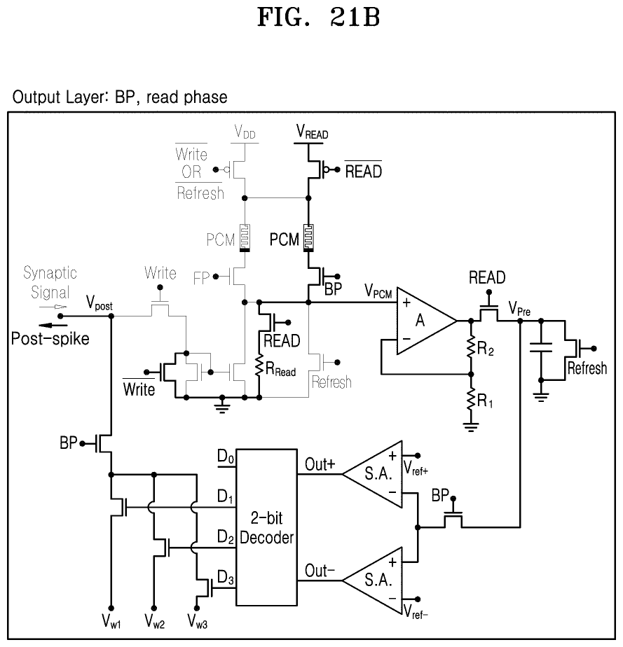

The neurons of the output layer are allowed to (e.g., are caused to and/or are controlled to be configured to) operate in the backward propagation read phase and the neurons of the hidden layer are allowed to (e.g., are caused to and/or are controlled to be configured to) operate in the forward propagation read phase so that a weight between the hidden layer and the output layer is updated based on said allowing (e.g., controlling) in operation S1470. In detail, in operation S1470, in a state where only elements illustrated dark in FIGS. 21A and 21B are activated and elements illustrated pale in FIGS. 21A and 21B are deactivated, the neurons of the output layer (e.g., neurons 131, as shown in FIG. 21B) may operate (e.g., may be caused to operate and/or may be controlled to be configured to operate) in the backward propagation read phase and provide the post-spikes 0V, −V₁, and −V₃ based on the decision result (e.g., first decision result), and the neurons of the hidden layer (e.g., neurons 121, as shown in FIG. 21A) may operate (e.g., may be caused to operate and/or may be controlled to be configured to operate) in the forward propagation read phase and provide a pre-spike ranging from 0V to V₁ based on the forward propagation signal stored therein. Operation S1470 may be implemented based on one or more control circuits of the neural network device 100 (e.g., control circuit 160, 170, and/or 180) controlling some or all of output layer 130 and/or the hidden layer 120, including controlling some or all of the neurons 131 of the output layer 130 and/or the neurons 121 of the hidden layer 120.

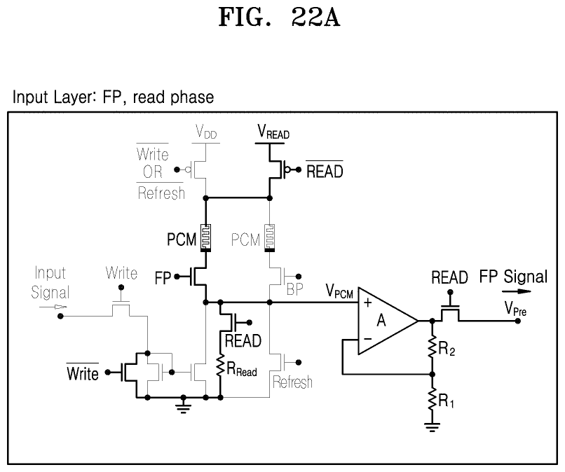

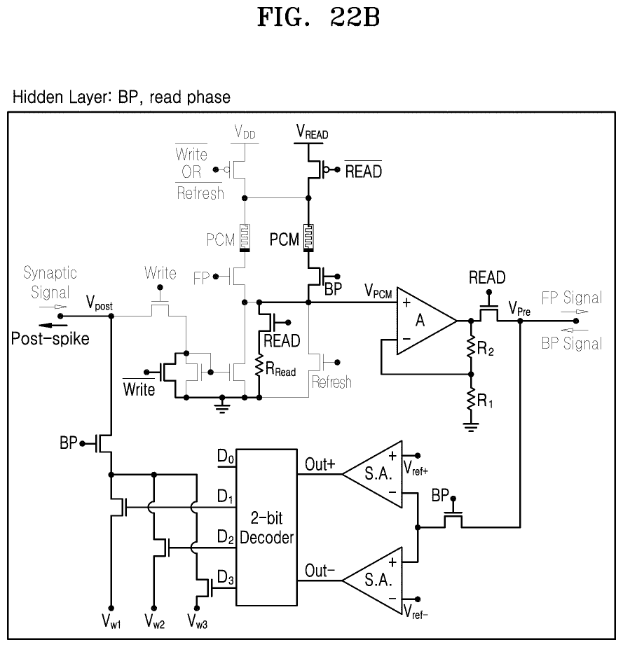

The neurons of the hidden layer are allowed to (e.g., are caused to and/or are controlled to be configured to) operate in the backward propagation read phase and the neurons of the input layer are allowed to (e.g., are caused to and/or are controlled to be configured to) operate in the forward propagation read phase so that a weight between the input layer and the hidden layer is updated in operation S1480. In detail, in operation S1480, in a state where only elements illustrated dark in FIGS. 22A and 22B are activated and elements illustrated pale in FIGS. 22A and 22B are deactivated, the neurons of the hidden layer (e.g., neurons 121, as shown in FIG. 22B) may operate (e.g., may be caused to operate and/or may be controlled to be configured to operate) in the backward propagation read phase and provide the post-spikes 0V, −V₁, and −V₃ based on the decision result (e.g., second decision result), and the neurons of the input layer (e.g., neurons 111, as shown in FIG. 22A) may operate (e.g., may be caused to operate and/or may be controlled to be configured to operate) in the forward propagation read phase and provide the pre-spike ranging from 0V to V₁ based on the forward propagation signal stored therein. Operation S1480 may be implemented based on one or more control circuits of the neural network device 100 (e.g., control circuit 150, 160, and/or 180) controlling some or all of hidden layer 120 and/or the input layer 110, including controlling some or all of the neurons 121 of the hidden layer 120 and/or the neurons 111 of the input layer 110.

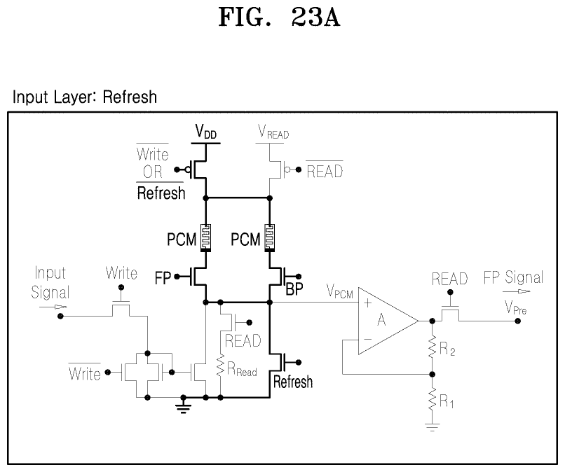

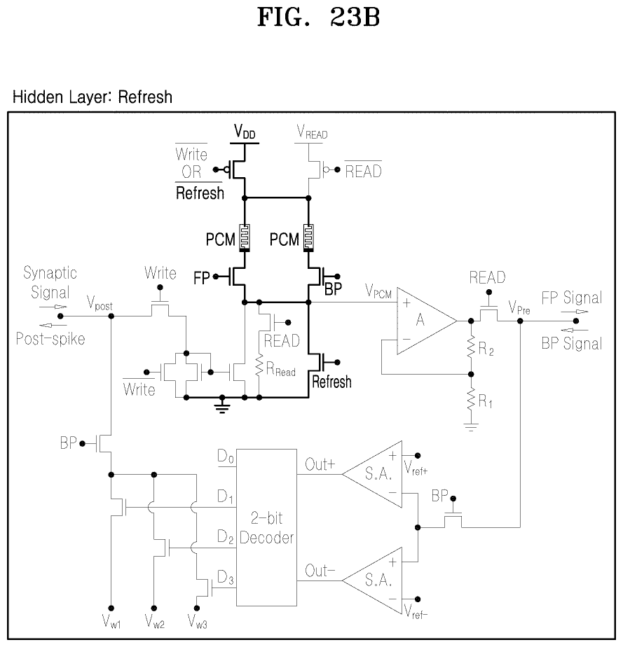

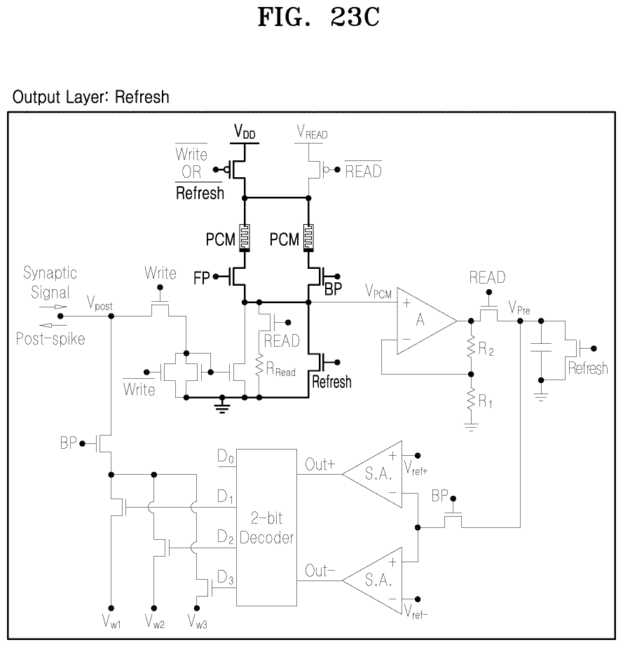

In a state where only elements illustrated dark in FIGS. 23A, 23B, and 23C are activated and elements illustrated pale in FIGS. 23A, 23B, and 23C are deactivated, all neurons are refreshed (e.g., reset) in operation S1490. Operation S1490 may be implemented based on one or more control circuits of the neural network device 100 (e.g., control circuit 150, 160, 170, and/or 180) controlling some or all of input layer 110, hidden layer 120, and/or the input layer 110, including controlling some or all of the neurons 111 of the input layer 110, the neurons 121 of the hidden layer 120, and/or the neurons 111 of the input layer 110.

The operation S1490 may be an initialization operation of the next iteration. During the operation S1490, for example, the PCM devices may be reset. As a result, the data stored in PCM devices may be erased. After the operation S1490, the resistance of PCM devices may be reset to maximum value. It allows new date storing in the PCM devices.

Operations S1410 through S1490 are repeated during a preset generation, and all the neurons of the neural network device may be reset in operation S1490 to prepare for operations of the next generation.

In operations S1410 through S1490 in the operating method of the neural network device described above, V_{W1}, V_{W2}, V_{W3}, and V_{ref} of each of the output layer and the hidden layer in each phase are shown in Table 5. V_{W1}, V_{W2}, and V_{W3} may the output of post-spike module 310. V_{ref} may be a preset value.

TABLE 5

| | Phase | Operation | V_{W1} | V_{W2} | V_{W3} | V_{ref} |
|---|---|---|---|---|---|---|
| Output | Backward | S1450 | V_{W, low} | V_{W, high} | V_{W, mid} | V_{label} |
| layer | propagation | | | | | |
| | (BP) write | | | | | |
| | BP read | S1460 | V_{high} | V_{low} | V_{mid} | (½)V₁ |
| | BP read | S1470 | −V₃ | −V₁ | GND | (½)V₁ |
| Hidden | BP write | S1460 | V_{W, low} | V_{W, high} | V_{W, mid} | V_{mid} |
| layer | BP read | S1480 | −V₃ | −V₁ | GND | (½)V₁ |

As described above, in an operating method of a neural network device according to some example embodiments, each of a weight between a hidden layer and an output layer and a weight between an input layer and the hidden layer may be updated in a single operation according to a post-spike provided from each of the neurons of the output layer and the neurons of the hidden layer, as in operation S1470 or S1480, thereby overcoming a disadvantage of a neural network device according to the related art, in which a synaptic weight needs to be updated through many operations to be an expected weight.

Any of the elements disclosed above, including some or all of the neural network device according to any of the example embodiments, may include and/or be implemented in processing circuitry which may include hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A neural network device based on a phase-change material (PCM), the neural network device comprising:
a plurality of neurons, the plurality of neurons including
a first plurality of neurons in an input layer,
a second plurality of neurons in a hidden layer, and
a third plurality of neurons in an output layer; and
a plurality of PCMs connecting an input line of the input layer to a connection line of the hidden layer and connecting the connection line of the hidden layer to an output line of the output layer,
wherein the first, second, and third pluralities of neurons have different structural configurations in different layers among the input layer, the hidden layer, and the output layer.

2. The neural network device of claim 1, wherein
each neuron of the first plurality of neurons of the input layer includes
a basic circuitry including a first PCM device and a second PCM device, the first PCM device configured to store a forward propagation signal, the second PCM device configured to store a backward propagation signal, and
a voltage driver circuitry configured to provide an output signal in a read range, each neuron of the second plurality of neurons of the hidden layer includes
the basic circuitry,
the voltage driver circuitry,
a post-spike circuitry configured to
provide a post-spike in a backward propagation read phase to update a synaptic weight during the backward propagation read phase,
provide the backward propagation signal during the backward propagation read phase, and
provide a write signal for writing at a PCM neuron during a backward propagation write phase, and
a decision circuitry configured to compare the backward propagation signal with a reference signal, and
each neuron of the third plurality of neurons of the output layer includes
the basic circuitry,
the voltage driver circuitry,
the post-spike circuitry,
the decision circuitry, and
a temporary storage circuitry configured to store an output signal of the output layer during a forward propagation read phase.

3. The neural network device of claim 2, wherein the neural network device is configured to update a weight between the hidden layer and the output layer and to update a weight between the input layer and the hidden layer in a single operation according to a post-spike provided from each neuron of the third plurality of neurons of the output layer and the second plurality of neurons of the hidden layer.

4. The neural network device of claim 1, further comprising:
at least one control circuit configured to synchronize timings of pulses that are output from the plurality of neurons.

5. The neural network device of claim 4, wherein the at least one control circuit includes a global control circuit and a plurality of sub control circuits that are controlled based on the global control circuit and are configured to synchronize timings of pulses that are output from separate, respective pluralities of neurons of the first plurality of neurons, the second plurality of neurons, and the third plurality of neurons.

6. The neural network device of claim 5, wherein
the plurality of sub control circuits includes
a level 1 control circuit configured to synchronize timings of pulses output from the first plurality of neurons of the input layer,
a level 2 control circuit configured to synchronize timings of pulses output from the second plurality of neurons of the hidden layer, and
a level 3 control circuit configured to synchronize timings of pulses output from the third plurality of neurons of the output layer; and
the global control circuit is configured to control the level 1 control circuit, the level 2 control circuit, and the level 3 control circuit.

7. An operating method of a neural network device based on a phase-change material (PCM), the neural network device including a plurality of neurons, the plurality of neurons including a first plurality of neurons in an input layer, a second plurality of neurons in a hidden layer, and a third plurality of neurons in an output layer, the operating method comprising:
controlling the first plurality of neurons of the input layer to configure the first plurality of neurons of the input layer to operate in a forward propagation write phase and to store data;
controlling the second plurality of neurons of the hidden layer to configure the second plurality of neurons of the hidden layer to operate in the forward propagation write phase and to convert data provided from the first plurality of neurons of the input layer;
controlling the third plurality of neurons of the output layer to configure the third plurality of neurons of the output layer to operate in the forward propagation write phase and to convert data provided from the second plurality of neurons of the hidden layer;
controlling the third plurality of neurons of the output layer to configure the third plurality of neurons of the output layer to operate in a forward propagation read phase and to temporarily store an output signal of the output layer;
selecting an operation on the output layer and storing a first decision result;
selecting an operation on the hidden layer and storing a second decision result;
updating a weight between the hidden layer and the output layer based on controlling the third plurality of neurons of the output layer to configure the third plurality of neurons of the output layer to operate in a backward propagation read phase and controlling the second plurality of neurons of the hidden layer to configure the second plurality of neurons of the hidden layer to operate in the forward propagation read phase;
updating a weight between the input layer and the hidden layer based on controlling the second plurality of neurons of the hidden layer to configure the second plurality of neurons of the hidden layer to operate in the backward propagation read phase and controlling the first plurality of neurons of the input layer to configure the first plurality of neurons of the input layer to operate in the forward propagation read phase; and
refreshing the plurality of neurons.

8. The operating method of claim 7, wherein
the controlling the second plurality of neurons of the hidden layer to configure the second plurality of neurons of the hidden layer to operate in the forward propagation write phase and to convert the data provided from the first plurality of neurons of the input layer includes, concurrently with the first plurality of neurons of the input layer operating in the forward propagation read phase, controlling the second plurality of neurons of the hidden layer to configure the second plurality of neurons of the hidden layer to operate in the forward propagation write phase and to store a synaptic signal based on combining forward propagation signals output from the first plurality of neurons of the input layer, and
the controlling the third plurality of neurons of the output layer to operate in the forward propagation write phase and to convert the data provided from the second plurality of neurons of the hidden layer includes, concurrently with the second plurality of neurons of the hidden layer operating in the forward propagation read phase, controlling the third plurality of neurons of the output layer to configure the third plurality of neurons of the output layer to operate in the forward propagation write phase and to store a separate synaptic signal based on combining forward propagation signals output from the second plurality of neurons of the hidden layer.

9. The operating method of claim 8, wherein
the selecting the operation on the output layer and storing of the first decision result includes controlling the third plurality of neurons of the output layer to configure the third plurality of neurons of the output layer to operate in a backward propagation write phase, to compare a combined backward propagation signal with a first reference, and to store the first decision result in the hidden layer, and
the selecting the operation on the hidden layer and storing of the second decision result includes, concurrently with the third plurality of neurons of the output layer operating in the backward propagation read phase, controlling the second plurality of neurons of the hidden layer to configure the second plurality of neurons of the hidden layer to operate in the backward propagation write phase, to combine backward propagation signals provided from the third plurality of neurons of the output layer, to compare a combination result with a second reference, and to store the second decision result in the hidden layer.

10. The operating method of claim 7, wherein
the updating of the weight between the hidden layer and the output layer includes
controlling the third plurality of neurons of the output layer to configure the third plurality of neurons of the output layer to operate in the backward propagation read phase and to provide post-spikes based on the first decision result, and
controlling the second plurality of neurons of the hidden layer to configure the second plurality of neurons of the hidden layer to operate in the forward propagation read phase and to provide pre-spikes based on forward propagation signals stored therein, and
the updating of the weight between the input layer and the hidden layer includes
controlling the second plurality of neurons of the hidden layer to configure the second plurality of neurons of the hidden layer to operate in the backward propagation read phase and to provide the post-spikes based on the second decision result; and
controlling the first plurality of neurons of the input layer to configure the first plurality of neurons of the input layer to operate in the forward propagation read phase and to provide pre-spikes based on the forward propagation signals stored therein.

11. The operating method of claim 7, wherein
the operating method is repeatedly performed in a preset generation, and
the refreshing the plurality of neurons includes resetting the plurality of neurons to prepare for an operation of a next generation.
